(19) United States
(12) Patent Application Publication
(10) Pub. No.: US 2025/0210400 A1
(43) Pub. Date: Jun. 26, 2025

(54) CARRIER SUBSTRATE AND METHOD OF MANUFACTURING SEMICONDUCTOR PACKAGE BY USING THE SAME

(71) Applicant: Samsung Electronics Co., Ltd., Suwon-si (KR)

(72) Inventors: Taehoon Kim, Suwon-si (KR); Jihye Shim, Suwon-si (KR)

(21) Appl. No.: 18/829,907

(22) Filed: Sep. 10, 2024

(30) Foreign Application Priority Data
Dec. 26, 2023 (KR) 10-2023-0191850

(51) Int. Cl. H01L 21/683; H01L 21/48; H01L 21/56; H01L 23/00

(52) U.S. Cl. CPC H01L 21/6835; H01L 21/4857; H01L 21/561; H01L 24/97; H01L 2221/68359; H01L 2224/95001

(57) ABSTRACT

A carrier substrate includes a main layer including and extending between a first surface and a second surface opposite to each other, a first trench extending from the first surface of the carrier substrate into the main layer, and a first organic pattern inside the first trench. A method of manufacturing a semiconductor package includes providing such a carrier substrate, disposing a semiconductor chip on the carrier substrate, and forming a redistribution layer electrically connected to the semiconductor chip.

### CROSS-REFERENCE TO RELATED APPLICATION

This application is based on and claims priority under 35 U.S.C. § 119 to Korean Patent Application No. 10-2023-0191850, filed on Dec. 26, 2023, in the Korean Intellectual Property Office, the disclosure of which is incorporated by reference herein in its entirety.

### BACKGROUND

The inventive concept relates to a carrier substrate and a method of manufacturing a semiconductor package by using the same.

For the past tens of years, computing power and wireless communication technologies have been rapidly developed according to discovery of techniques, materials, and manufacturing processes. Accordingly, implementation of high integration of high-performance transistors is possible and the speed of integration has increased twice about every 18 months according to Moore's law. A light, thin, short, and small system and power efficiency of the system are permanent goals of the semiconductor manufacturing industry, and at the present time approaching economical and physical process limitation, three-dimensional (3D) integration packaging is suggested as an effective solution.

Development of a three-dimensionally integrated device started from a complementary metal oxide semiconductor (CMOS) integrated device launched in 1980 and then has been conducted through continuous research and development for over 40 years. Examples of the 3D integration technology include integration of a logic circuit and a memory circuit, sensor packaging, heterogeneous integration of a microelectrochemical system (MEMS) and a CMOS, and the like. The 3D integration technology enables not only reduction of a form factor but also achievement of high reliability, low power consumption, and low manufacturing costs. Typical 3D and other types of semiconductor products utilize carrier substrates in their manufacture. However, the use of a carrier substrate can result in warpage due to differences in coefficients of thermal expansion between the carrier substrate and a wafer being processed.

### SUMMARY

Aspects of the inventive concept provide a carrier substrate with improved performance and reliability.

Aspects of the inventive concept also provide a method of manufacturing a semiconductor package with improved performance and reliability.

The problems to be solved by the technical idea of the inventive concept are not limited to the problems mentioned above, and other problems, which are not mentioned, could be clearly understood by those of ordinary skill in the art from the description below.

According to an aspect of the inventive concept, a carrier substrate includes a main layer including and extending between a first surface and a second surface opposite to each other, a first trench extending from the first surface of the carrier substrate into the main layer, and a first organic pattern inside the first trench.

According to another aspect of the inventive concept, a method of manufacturing a semiconductor package includes providing a carrier substrate, disposing a semiconductor chip on the carrier substrate, and forming a redistribution layer electrically connected to the semiconductor chip, wherein the carrier substrate includes a first surface and a second surface opposite to each other, a main layer including and extending between the first surface and the second surface, a first trench extending from the first surface of the carrier substrate into the main layer, and a first organic pattern inside the first trench.

According to another aspect of the inventive concept, a method of manufacturing a semiconductor package includes providing a carrier substrate, forming, on a front surface of the carrier substrate, a redistribution layer including a redistribution insulating layer and a redistribution pattern surrounded by the redistribution insulating layer, and disposing a semiconductor chip on the redistribution layer and electrically connecting the semiconductor chip to the redistribution pattern, wherein the carrier substrate includes the front surface and a rear surface opposite to the front surface, a main layer including and extending between the rear surface and the front surface, a front trench extending from the front surface of the carrier substrate into the main layer, and a front organic pattern inside the front trench, wherein a thermal expansion coefficient of the main layer is less than a thermal expansion coefficient of the front organic pattern, and the thermal expansion coefficient of the main layer is less than a thermal expansion coefficient of the redistribution insulating layer.

### BRIEF DESCRIPTION OF THE DRAWINGS

Embodiments of the inventive concept will be more clearly understood from the following detailed description taken in conjunction with the accompanying drawings in which:

FIG. 1 is a perspective view of a carrier substrate according to embodiments;

FIG. 2 is a top-down view of a carrier substrate according to embodiments;

FIG. 3 is a cross-sectional view of a carrier substrate according to embodiments;

FIGS. 4A and 4B are cross-sectional views of carrier substrates according to other embodiments;

FIGS. 5A and 5B are cross-sectional views of carrier substrates according to other embodiments;

FIGS. 6 and 7 are top-down views of carrier substrates according to other embodiments;

FIGS. 8 and 9 are cross-sectional views for describing a carrier substrate according to embodiments;

FIG. 10 is a top-down view of a carrier substrate according to embodiments;

FIG. 11 is a cross-sectional view of a carrier substrate according to embodiments;

FIGS. 12A to 12C are top-down views of carrier substrates according to embodiments;

FIGS. 13 and 14 are top-down views of carrier substrates according to embodiments;

FIGS. 15 to 18 are cross-sectional views of carrier substrates according to embodiments;

FIGS. 19A to 19M are cross-sectional views illustrating a method of manufacturing a semiconductor package, according to embodiments; and

FIGS. 20A to 20E are cross-sectional views illustrating a method of manufacturing a semiconductor package, according to embodiments.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted. In the drawings, the thicknesses or sizes of layers are exaggerated for convenience and clarity of description and are thus somewhat different from actual shapes and ratios.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

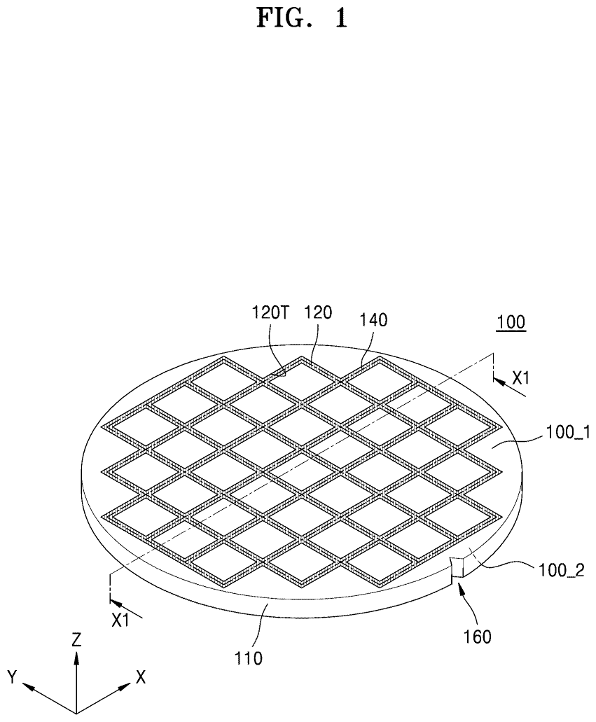

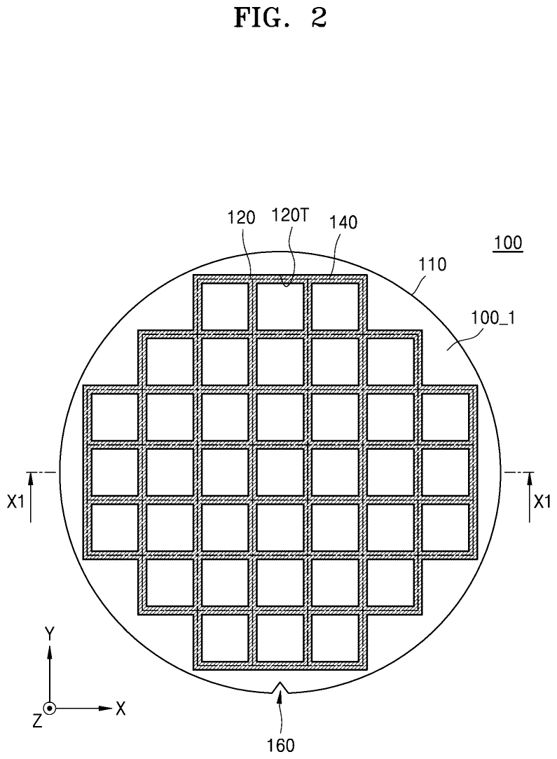

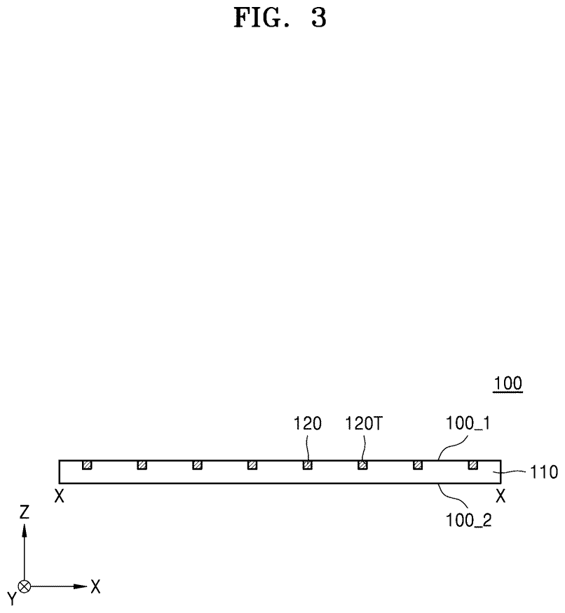

FIG. 1 is a perspective view of a carrier substrate 100 according to embodiments. FIG. 2 is a top-down view of the carrier substrate 100 according to embodiments. FIG. 3 is a cross-sectional view of the carrier substrate 100 according to embodiments.

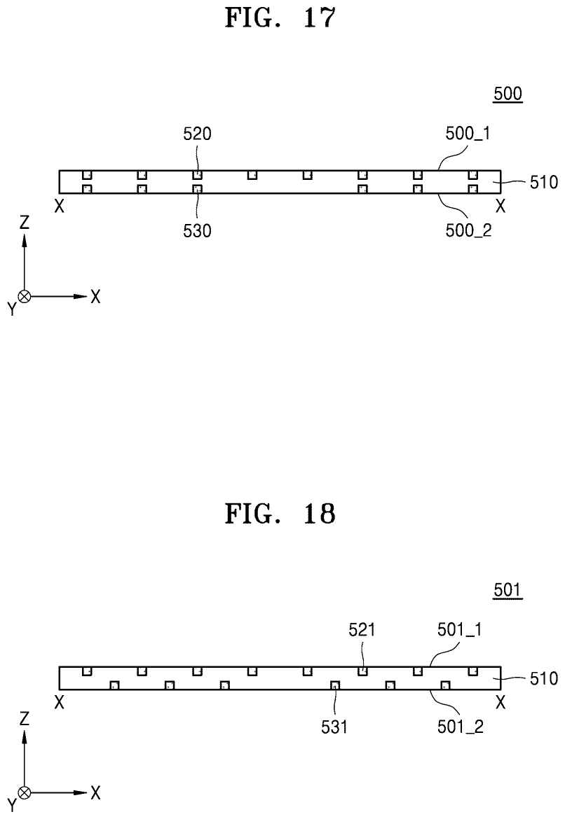

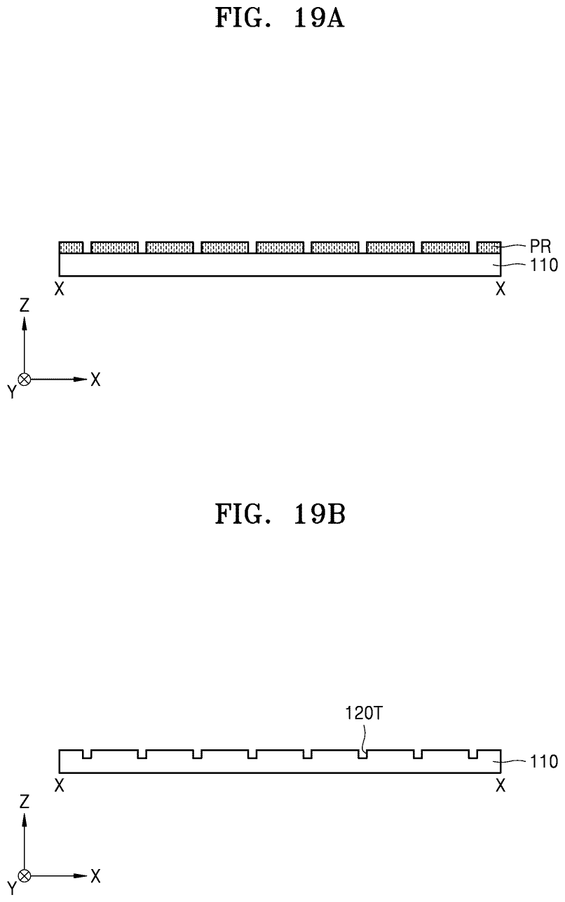

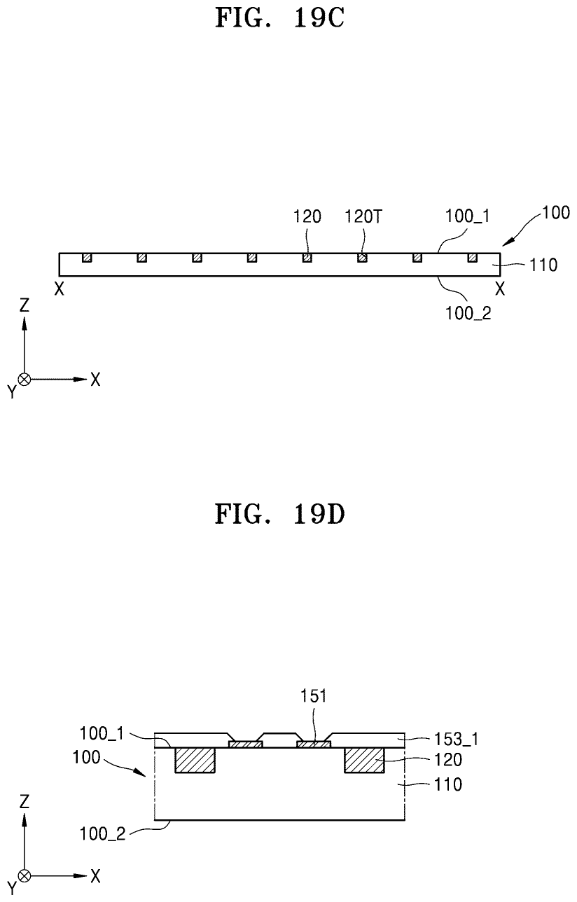

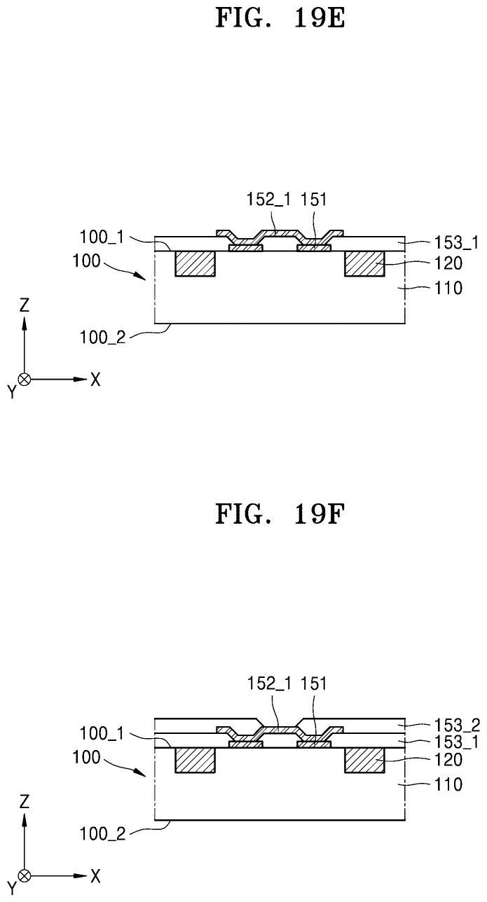

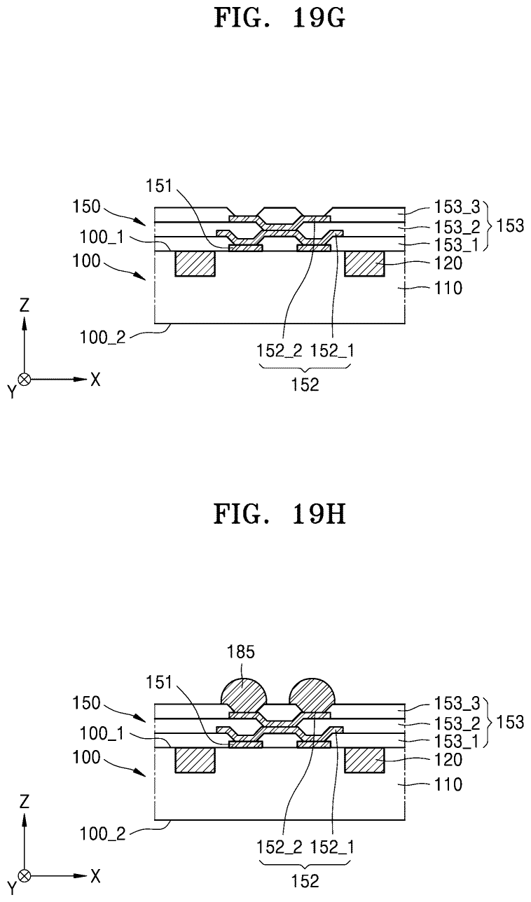

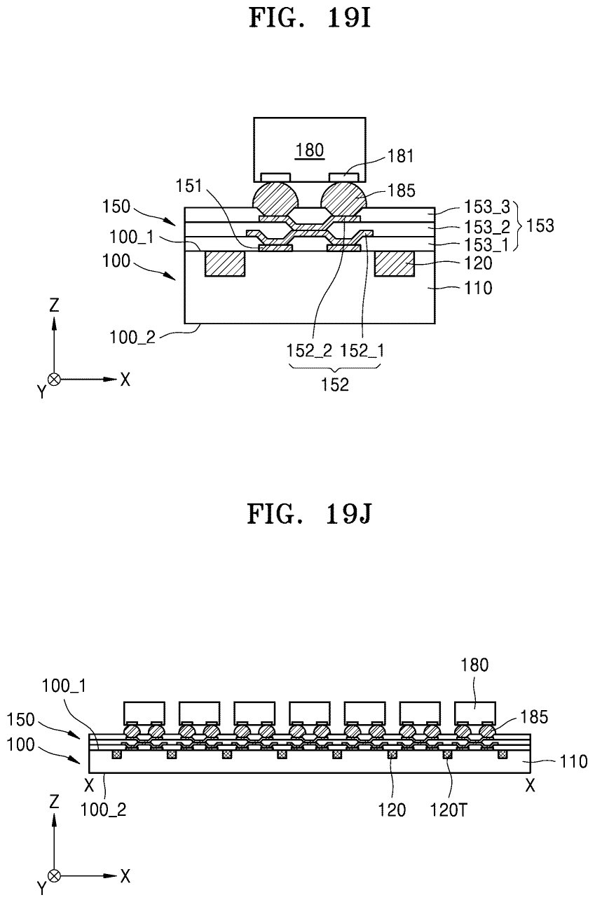

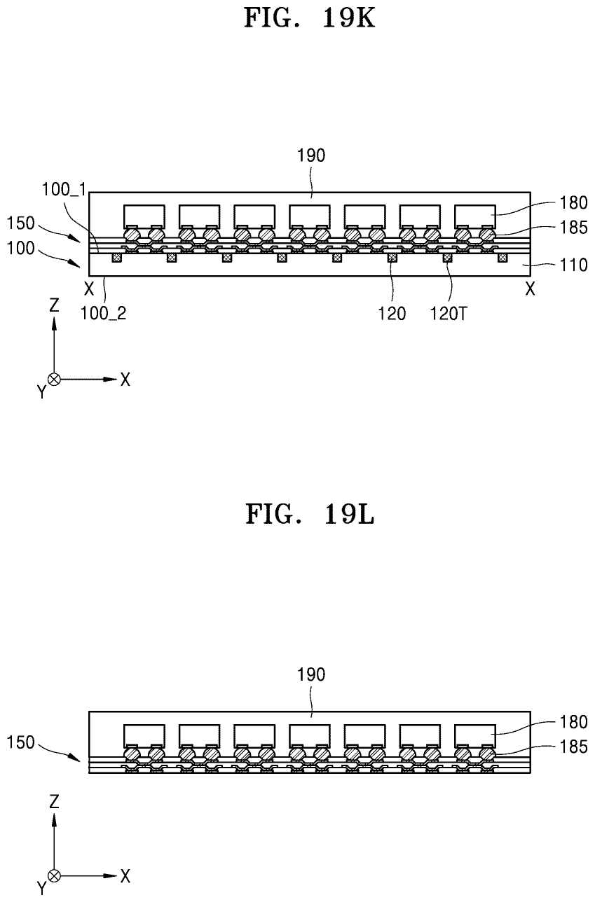

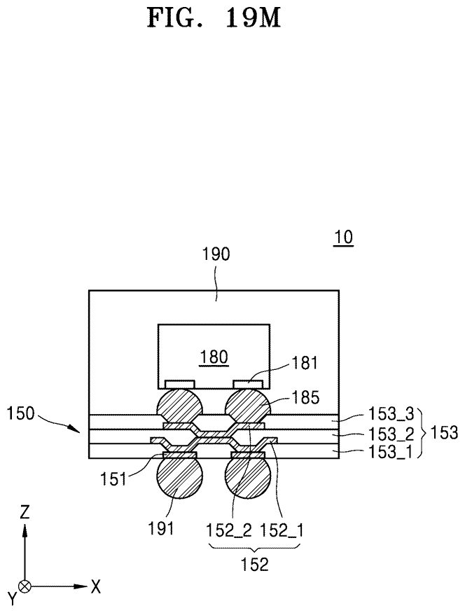

Referring to FIGS. 1 to 3, the carrier substrate 100 may include a front surface 100_1 and a rear surface 100_2 opposite to each other. In the specification, the front surface 100_1 of the carrier substrate 100 may be a surface facing a vertically up direction (a +Z direction). The rear surface 100_2 of the carrier substrate 100 may be a surface facing a vertically down direction (a −Z direction). In some embodiments, the front surface 100_1 of the carrier substrate 100 may be a surface on which a semiconductor chip 180 is disposed in a process of manufacturing a semiconductor package 10 (see FIGS. 19A to 19M), which is to be described below.

In some embodiments, the carrier substrate 100 may include a main layer 110. The main layer 110 may include a front surface and a rear surface opposite to each other, wherein the front surface and the rear surface of the main layer 110 may include the front surface 100_1 and the rear surface 100_2 of the carrier substrate 100, respectively. For example, the front surface of the main layer 110 may face the vertically up direction (the +Z direction) and the rear surface of the main layer 110 may face the vertically down direction (the −Z direction). For example, the front surface of the main layer 110 may be the surface on which the semiconductor chip 180 is disposed in the process of manufacturing the semiconductor package 10 (see FIGS. 19A to 19M), which is to be described below. The main layer 110 may also be described as a core layer or a base layer.

In some embodiments, the main layer 110 may include one selected from a silicon layer and a germanium layer. In some embodiments, the main layer 110 may include a glass material. In some embodiments, the main layer 110 may include alumina.

In some embodiments, a front trench 120T may be on the front surface 100_1 of the carrier substrate 100. In some embodiments, a front organic pattern 120 may be inside the front trench 120T.

In some embodiments, the front trench 120T of the carrier substrate 100 may include a lattice shape. For example, the front trench 120T of the carrier substrate 100 may include a lattice shape extending in a first horizontal direction (an X direction) and a second horizontal direction (a Y direction).

In some embodiments, the front organic pattern 120 may include an organic material. In some embodiments, the thermal expansion coefficient of the main layer 110 may be different from the thermal expansion coefficient of the front organic pattern 120. In some embodiments, the thermal expansion coefficient of the main layer 110 may be less than the thermal expansion coefficient of the front organic pattern 120.

In some embodiments, a scribe line 140 may be on the front surface 100_1 of the carrier substrate 100. The scribe line 140 may indicate a boundary of a region in which the semiconductor chip 180 is disposed in the process of manufacturing the semiconductor package 10 (see FIG. 19F), which is to be described below. The scribe line 140 may be a line along which a molding layer 190 molding the semiconductor chip 180 is cut after disposing the semiconductor chip 180 in the process of manufacturing the semiconductor package 10 (see FIG. 19F), which is to be described below. In some embodiments, the scribe line 140 may not be an actual visible line on the carrier substrate 100, and therefore a visible line will not be directly cut. In some embodiments, the scribe line 140 of the carrier substrate 100 may include a lattice shape. For example, the scribe line 140 of the carrier substrate 100 may include a lattice shape of lines extending in the first horizontal direction (the X direction) and the second horizontal direction (the Y direction).

In some embodiments, the front organic pattern 120 may be formed in the vicinity of the scribe line 140, for example to overlap the scribe line 140. Particularly, a region of the front trench 120T in which the front organic pattern 120 is disposed may include the scribe line 140. The front organic pattern 120 may cover a region where the scribe line 140 is located. Items described in the singular herein may be provided in plural, as can be seen, for example, in the drawings. Thus, the description of a single item (e.g., scribe line) that is provided in plural should be understood to be applicable to the remaining plurality of items unless context indicates otherwise. For example, as can be seen from FIG. 1, a plurality of scribe lines 140 may be included, and a plurality of intersecting trenches 120T and corresponding front organic line patterns 120 may be formed to respectively cover the region where the plurality of scribe lines 140 are located. As shown in the embodiment of FIGS. 1 and 2, each front organic line pattern 120 may have a straight line shape. In one embodiment, the front trench 120T and the corresponding organic line pattern 120 may have a rectangular cross-sectional shape, having vertical sidewalls and a horizontal bottom surface.

In some embodiments, the carrier substrate 100 may include a notch 160. In some embodiments, the front organic pattern 120 of the carrier substrate 100 may extend in the same direction as the direction of a diameter of the carrier substrate 100 that ends at the notch 160, i.e., the second horizontal direction (the Y direction), and a direction, i.e., the first horizontal direction (the X direction), perpendicular to the direction of the notch 160.

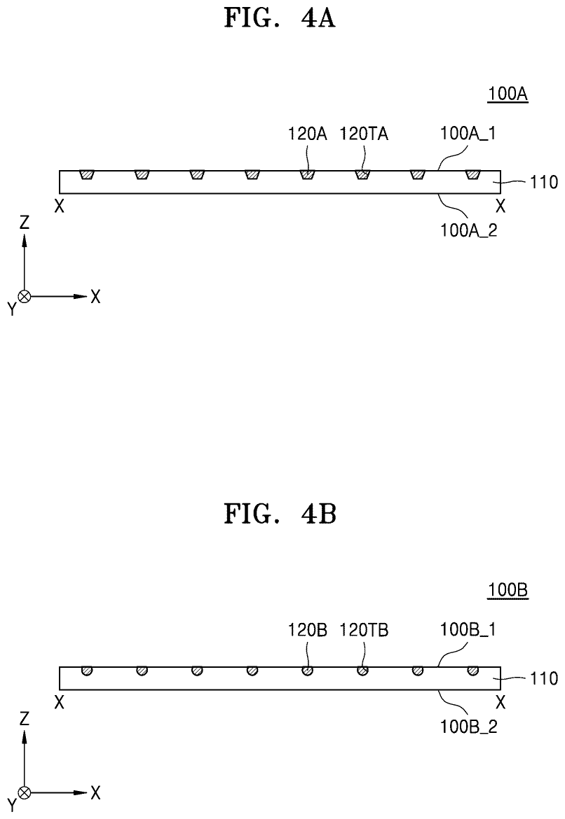

FIGS. 4A and 4B are cross-sectional views of carrier substrates 100A and 100B according to other embodiments. Hereinafter, the differences from the carrier substrate 100 described with reference to FIGS. 1 to 3 are mainly described.

Referring to FIG. 4A, the carrier substrate 100A may include a front surface 100A_1 and a rear surface 100A_2 opposite to each other and the main layer 110. A front trench 120TA may be on the front surface 100A_1 of the carrier substrate 100A. A front organic pattern 120A may be inside the front trench 120TA.

In some embodiments, the front trench 120TA of the carrier substrate 100A may have an upper horizontal width that is greater than a lower horizontal width. For example, a cross-section of the front trench 120TA may have a trapezoidal shape with an upper horizontal width that is greater than a lower horizontal width. For example, the front trench 120TA of the carrier substrate 100A may have a horizontal width gradually decreasing downward.

Referring to FIG. 4B, the carrier substrate 100B may include a front surface 100B_1 and a rear surface 100B_2 opposite to each other and the main layer 110. A front trench 120TB may be in the front surface 100B_1 of the carrier substrate 100B. A front organic pattern 120B may be inside the front trench 120TB.

In some embodiments, the front trench 120TB of the carrier substrate 100B may have a horizontal width gradually increasing and then decreasing downward. For example, the front trench 120TB of the carrier substrate 100B may include a portion having a horizontal width that is greater than the horizontal width of the opening of the front trench 120TB. The front trench 120TB may have a curved shape (e.g., to be circular in some embodiments).

The different embodiments of FIG. 3 and FIGS. 4A and 4B may be interchangeably selected for the different additional embodiments described below.

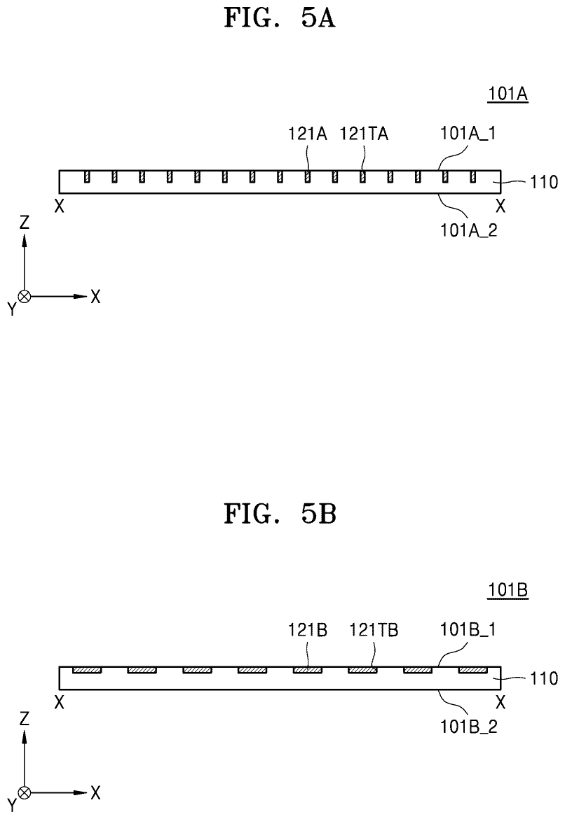

FIGS. 5A and 5B are cross-sectional views of carrier substrates 101A and 101B according to other embodiments.

Referring to FIGS. 5A and 5B, the horizontal widths, the depths, and the intervals of front trenches 121TA and 121TB of the carrier substrates 101A and 101B may be variously selected according to designs.

As shown in FIG. 5A, the carrier substrate 101A may include a front surface 101A_1 and a rear surface 101A_2 opposite to each other and the main layer 110. A front trench 121TA may be in the front surface 101A_1 of the carrier substrate 101A. A front organic pattern 121A may be inside the front trench 121TA. For example, the horizontal width of each front trench 121TA may be less than the depth of each front trench 121TA.

As shown in FIG. 5B, the carrier substrate 101B may include a front surface 101B_1 and a rear surface 101B_2 opposite to each other and the main layer 110. A front trench 121TB may be in the front surface 101B_1 of the carrier substrate 101B. A front organic pattern 121B may be inside the front trench 121TB. For example, the horizontal width of each front trench 121TB may be greater than the depth of each front trench 121TB.

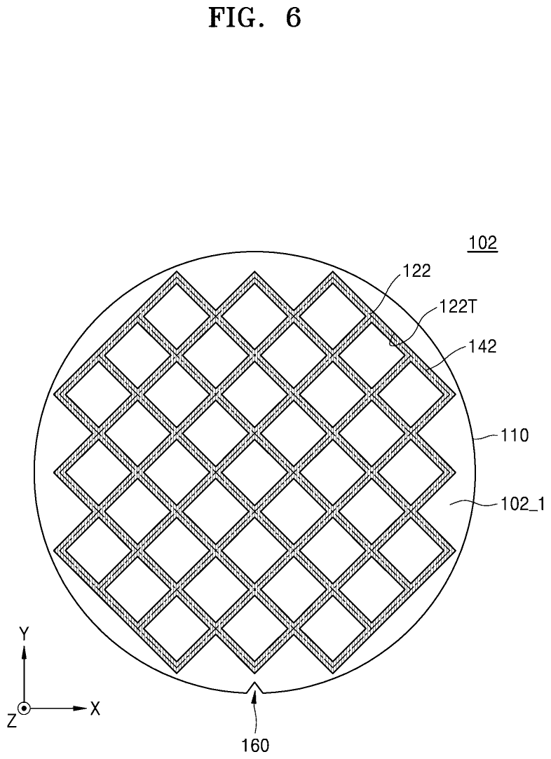

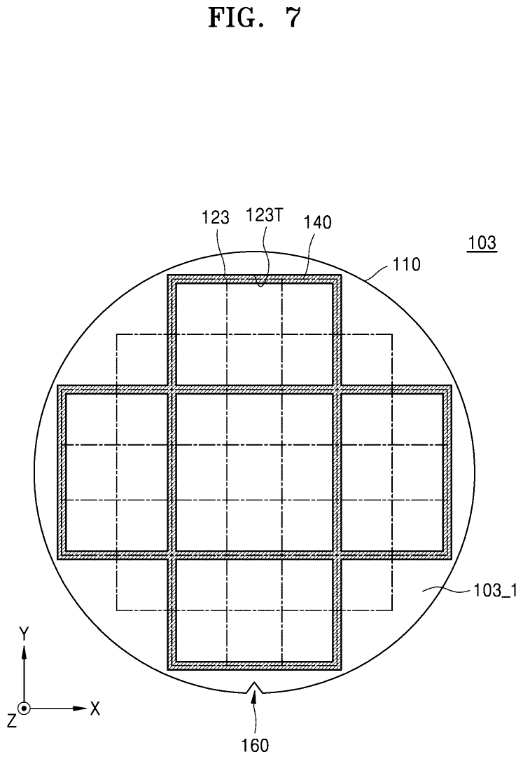

FIGS. 6 and 7 are top-down views of carrier substrates 102 and 103 according to other embodiments. Hereinafter, the differences from the carrier substrate 100 described with reference to FIGS. 1 to 3 are mainly described.

Referring to FIG. 6, a front organic pattern 122 (e.g., each front organic line pattern) of the carrier substrate 102 may extend in a direction crossing at 45° with respect to the direction of a diameter of the carrier substrate 100 that ends at the notch 160, i.e., the second horizontal direction (the Y direction). In some embodiments, each scribe line 142 and front trench 122T of the carrier substrate 102 may also extend in the direction crossing at 45° with respect to the direction of a diameter of the carrier substrate 100 that ends at the notch 160, i.e., the second horizontal direction (the Y direction).

Referring to FIG. 7, the carrier substrate 103 may include the scribe lines 140 and a front organic pattern 123 (e.g., front organic line patterns) on the main layer 110. The front organic pattern 123 may not be formed in the vicinity of (e.g., on) at least some of the scribe lines 140 of the carrier substrate 103. For example, the front organic pattern 123 of the carrier substrate 103 may not be formed in the vicinity of (e.g., on) all of scribe lines 140. The horizontal interval between front organic patterns 123 of the carrier substrate 103 may be greater than the horizontal interval between the scribe lines 140 of the carrier substrate 100.

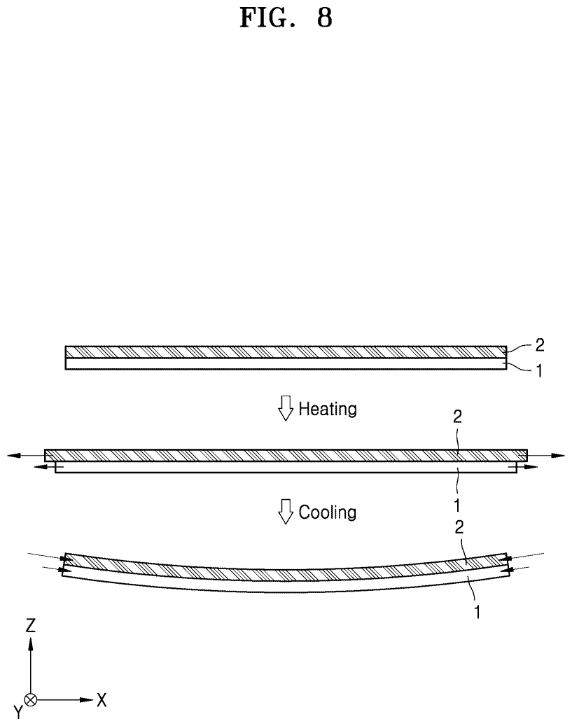

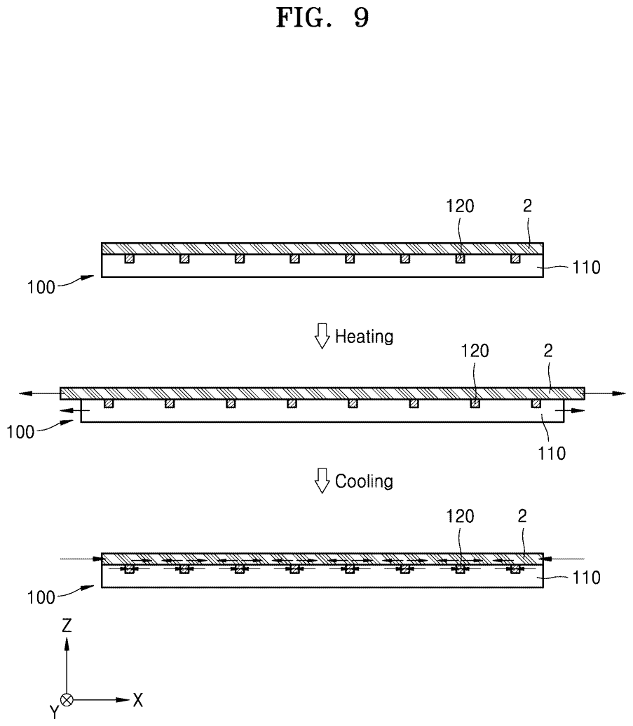

FIGS. 8 and 9 are cross-sectional views for describing the carrier substrate 100 according to embodiments. Particularly, FIG. 8 is a cross-sectional view of a carrier substrate 1 and a material layer 2 on the carrier substrate 1 according to a comparative example, which are heated and cooled during a process, to describe the carrier substrate 100. FIG. 9 is a cross-sectional view of the carrier substrate 100 and the material layer 2 on the carrier substrate 100, which are heated and cooled during a process, in comparison to the carrier substrate 1 according to the comparative example.

Referring to FIG. 8, the material layer 2 may be on the front surface of the carrier substrate 1. For example, the material layer 2 may include a material having a thermal expansion coefficient that is greater than that of the carrier substrate 1. During a semiconductor package manufacturing process, the carrier substrate 1 and the material layer 2 may be heated and cooled.

As shown in FIG. 8, when the carrier substrate 1 and the material layer 2 are heated, the carrier substrate 1 and the material layer 2 may expand. In this case, due to the thermal expansion coefficient difference, the degree of expansion of the carrier substrate 1 may differ from the degree of expansion of the material layer 2. For example, the degree of expansion of the carrier substrate 1 may be less than the degree of expansion of the material layer 2.

Thereafter, when the carrier substrate 1 and the material layer 2 are cooled, the carrier substrate 1 and the material layer 2 may contract. In this case, due to the thermal expansion coefficient difference, the degree of contraction of the carrier substrate 1 may differ from the degree of contraction of the material layer 2. For example, the degree of contraction of the carrier substrate 1 may be less than the degree of contraction of the material layer 2. The material layer 2 on the carrier substrate 1 may contract more than the carrier substrate 1, thereby causing warpage of the carrier substrate 1.

However, referring to FIG. 9, the material layer 2 may be on the front surface 100_1 (see FIG. 1) of the carrier substrate 100 according to embodiments. For example, the material layer 2 may include a material having a thermal expansion coefficient that is greater than that of the carrier substrate 100. During a semiconductor package manufacturing process, the carrier substrate 100 and the material layer 2 may be heated and cooled.

As shown in FIG. 9, when the carrier substrate 100 and the material layer 2 are heated, the carrier substrate 100 and the material layer 2 may expand. In this case, due to the thermal expansion coefficient difference, the degree of expansion of the carrier substrate 100 may differ from the degree of expansion of the material layer 2. For example, the degree of expansion of the carrier substrate 100 may be less than the degree of expansion of the material layer 2.

Thereafter, when the carrier substrate 100 and the material layer 2 are cooled, the carrier substrate 100 and the material layer 2 may contract. In this case, due to the thermal expansion coefficient difference, the degree of contraction of the carrier substrate 100 may differ from the degree of contraction of the material layer 2. For example, the degree of contraction of the carrier substrate 100 may be less than the degree of contraction of the material layer 2. In this case, when the carrier substrate 100 includes the front organic pattern 120 on a surface (i.e., the front surface 100_1 (see FIG. 1) of the carrier substrate 100) in contact with the material layer 2, the front organic pattern 120 may contract largely, thereby reducing warpage of the carrier substrate 100.

Particularly, as described above, the front organic pattern 120 may have a thermal expansion coefficient that is greater than that of the main layer 110. Therefore, when the carrier substrate 100 is cooled, the front organic pattern 120 may contract more than the main layer 110, thereby compensating for the difference in the degrees of contraction of the carrier substrate 100 and the material layer 2. Therefore, when the carrier substrate 100 includes the front organic pattern 120 on the front surface 100_1 (see FIG. 1) of the carrier substrate 100, warpage due to expansion and contraction of the carrier substrate 100 may be reduced. Particularly, when the material layer 2 having a thermal expansion coefficient that is greater than that of the main layer 110 of the carrier substrate 100 is on the front surface 100_1 (see FIG. 1) of the carrier substrate 100, the carrier substrate 100 including the front organic pattern 120 may have reduced warpage due to expansion and contraction.

Likewise, because the carrier substrates 100A, 100B, 101A, 101B, 102, and 103 shown in FIGS. 4A, 4B, 5A, 5B, 6, and 7 include the front organic patterns 120A, 120B, 121A, 121B, 122, and 123 on the front surfaces 100A_1, 100B_1, 101A_1, 101B_1, 102_1, and 103_1 of the carrier substrates 100A, 100B, 101A, 101B, 102, and 103, respectively, warpage of the carrier substrates 100A, 100B, 101A, 101B, 102, and 103 due to expansion and contraction may be reduced.

According to embodiments, the carrier substrates 100, 100A, 100B, 101A, 101B, 102, and 103 respectively including the front organic patterns 120, 120A, 120B, 121A, 121B, 122, and 123 may be provided. Particularly, according to embodiments, the carrier substrates 100, 100A, 100B, 101A, 101B, 102, and 103 of which warpage due to expansion and contraction is reduced may be provided. Therefore, according to embodiments, the carrier substrates 100, 100A, 100B, 101A, 101B, 102, and 103 with improved performance and reliability may be provided. According to the above embodiments, the main layer of the carrier substrates may be formed of a material such as silicon, germanium, glass, or alumina, and the front organic patterns may be formed of an organic material, such as polymers, including thermoplastic polymers such as polyethylene (PE), polypropylene (PP), polycarbonate (PC), polystyrene (PS), and polyvinyl chloride (PVC), with a larger thermal expansion coefficient than that of the carrier substrate. However, these are exemplary and the organic materials of the present invention are not limited to the substances described above.

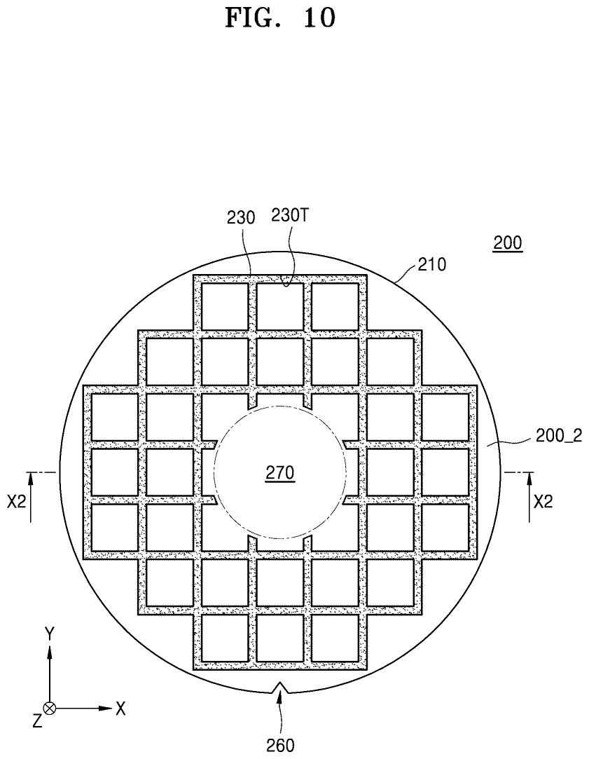

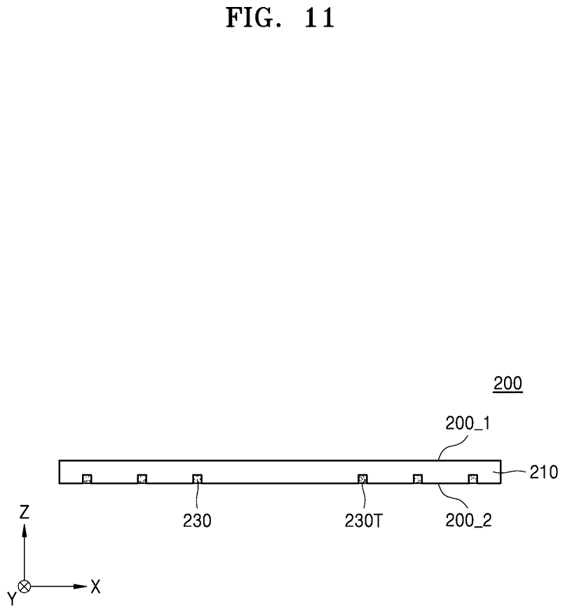

FIG. 10 is a top-down view of a carrier substrate 200 according to embodiments. FIG. 11 is a cross-sectional view of the carrier substrate 200 according to embodiments.

Referring to FIGS. 10 and 11, the carrier substrate 200 may include a front surface 200_1 and a rear surface 200_2. The front surface 200_1 of the carrier substrate 200 may be a surface facing the vertically up direction (the +Z direction). The rear surface 200_2 of the carrier substrate 200 may be a surface facing the vertically down direction (the −Z direction). In some embodiments, the front surface 200_1 of the carrier substrate 200 may be a surface on which a semiconductor chip is disposed in a semiconductor package manufacturing process. For example, the rear surface 200_2 of the carrier substrate 200 may be a surface on which pieces of process equipment are disposed in a semiconductor package manufacturing process.

In some embodiments, the carrier substrate 200 may include a main layer 210. The main layer 210 may include a front surface and a rear surface opposite to each other, wherein the front surface and the rear surface of the main layer 210 may include the front surface 200_1 and the rear surface 200_2 of the carrier substrate 200, respectively. For example, the front surface of the main layer 210 may face the vertically up direction (the +Z direction) and the rear surface of the main layer 210 may face the vertically down direction (the −Z direction). For example, the front surface of the main layer 210 may be a surface on which a semiconductor chip is disposed in a semiconductor package manufacturing process. For example, the rear surface of the main layer 210 may be a surface on which pieces of process equipment are disposed in a semiconductor package manufacturing process.

In some embodiments, a rear trench 230T may be on the rear surface 200_2 of the carrier substrate 200. In some embodiments, a rear organic pattern 230 may be inside the rear trench 230T.

In some embodiments, the rear trench 230T of the carrier substrate 200 may include a lattice shape. For example, the rear trench 230T of the carrier substrate 200 may include a lattice shape extending in the first horizontal direction (the X direction) and the second horizontal direction (the Y direction). Likewise, the rear organic pattern 230 of the carrier substrate 200 may include a lattice shape. For example, the rear organic pattern 230 of the carrier substrate 200 may include a lattice shape extending in the first horizontal direction (the X direction) and the second horizontal direction (the Y direction).

In some embodiments, the rear organic pattern 230 may include an organic material. In some embodiments, the thermal expansion coefficient of the main layer 210 may be different from the thermal expansion coefficient of the rear organic pattern 230. In some embodiments, the thermal expansion coefficient of the main layer 210 may be less than the thermal expansion coefficient of the rear organic pattern 230.

In some embodiments, the carrier substrate 200 may include a notch 260. In some embodiments, the rear organic pattern 230 (e.g., rear organic line patterns) of the carrier substrate 200 may extend in the same direction as the direction of a diameter of the carrier substrate 200 ending at the notch 260, i.e., the second horizontal direction (the Y direction), and a direction, i.e., the first horizontal direction (the X direction), perpendicular to the direction of the notch 260.

In some embodiments, the carrier substrate 200 may include an attachment region 270 on the rear surface 200_2 of the carrier substrate 200. For example, the attachment region 270 may be a region to which a chuck is attached in a semiconductor manufacturing process. For example, the chuck may be attached to the attachment region 270 of the carrier substrate 200 to support and/or fix the carrier substrate 200 during the semiconductor manufacturing process. In some embodiments, the attachment region 270 may be formed at the central portion of the rear surface 200_2 of the carrier substrate 200.

In some embodiments, the rear trench 230T of the carrier substrate 200 may not be formed in the attachment region 270. For example, the rear trench 230T of the carrier substrate 200 may be formed on the rear surface 200_2 except for the attachment region 270. Likewise, the rear organic pattern 230 may not be formed in the attachment region 270. For example, the rear trench 230T and the rear organic pattern 230 may not overlap the attachment region 270 in the vertical direction (the Z direction). A plurality of rear trenches 230T and rear organic patterns 230 may terminate at the attachment region 270, for example, so that at least two ends in a lengthwise direction of two adjacent rear trenches 230T end at the attachment region 270.

In some embodiments, because the carrier substrate 200 includes the rear organic pattern 230 on the rear surface 200_2 of the carrier substrate 200, warpage due to expansion and contraction of the carrier substrate 200 may be reduced.

Particularly, as described above, the rear organic pattern 230 may have a thermal expansion coefficient that is greater than that of the main layer 210. Therefore, when the carrier substrate 200 is cooled, the rear organic pattern 230 may contract more than the main layer 210. For example, when a material layer having a thermal expansion coefficient less than that of the main layer 210 of the carrier substrate 200 is on the front surface 200_1 of the carrier substrate 200, the rear organic pattern 230 may contract more than the main layer 210, thereby compensating for the difference in the degrees of contraction of the carrier substrate 200 and the material layer. Therefore, when the carrier substrate 200 includes the rear organic pattern 230 on the rear surface 200_2, warpage due to expansion and contraction of the carrier substrate 200 may be reduced.

According to embodiments, the carrier substrate 200 including the rear organic pattern 230 may be provided. Particularly, according to embodiments, the carrier substrate 200 of which warpage due to expansion and contraction is reduced may be provided.

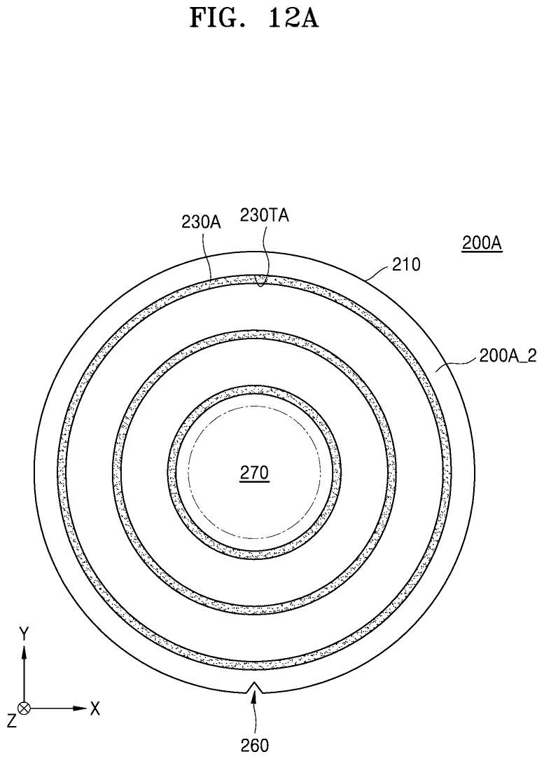

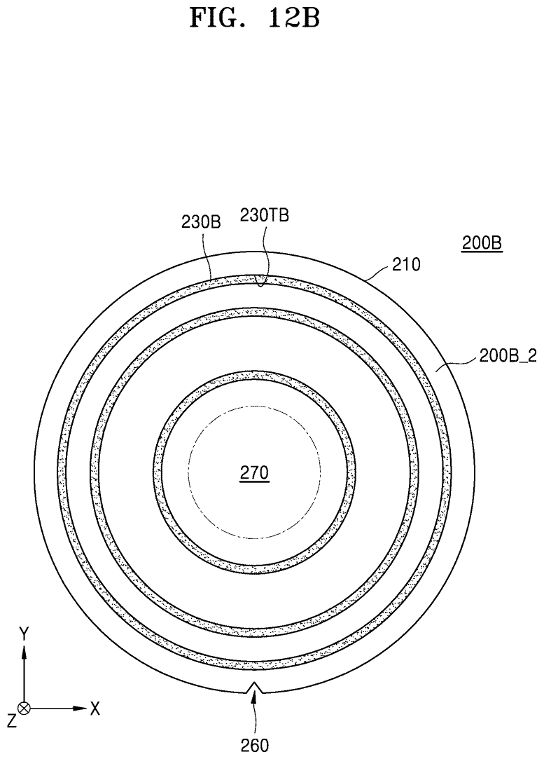

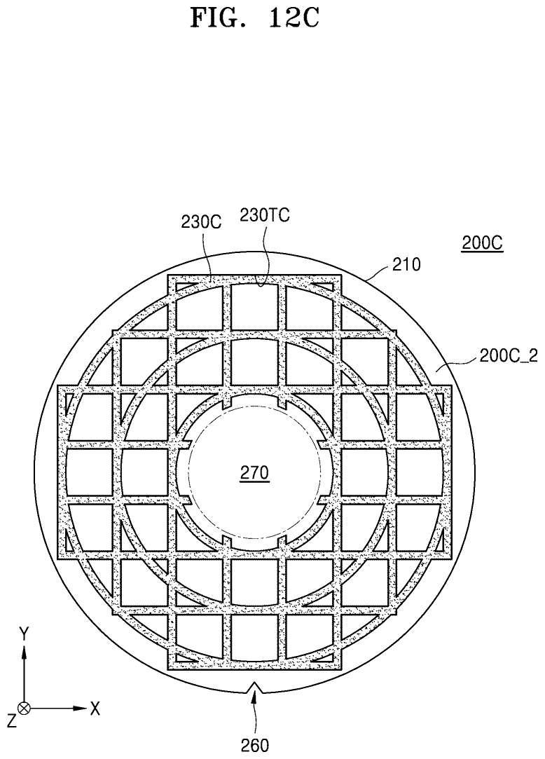

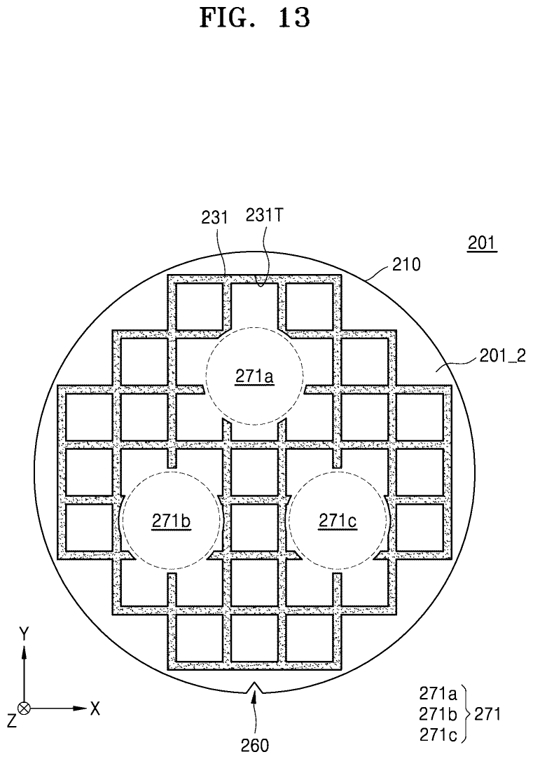

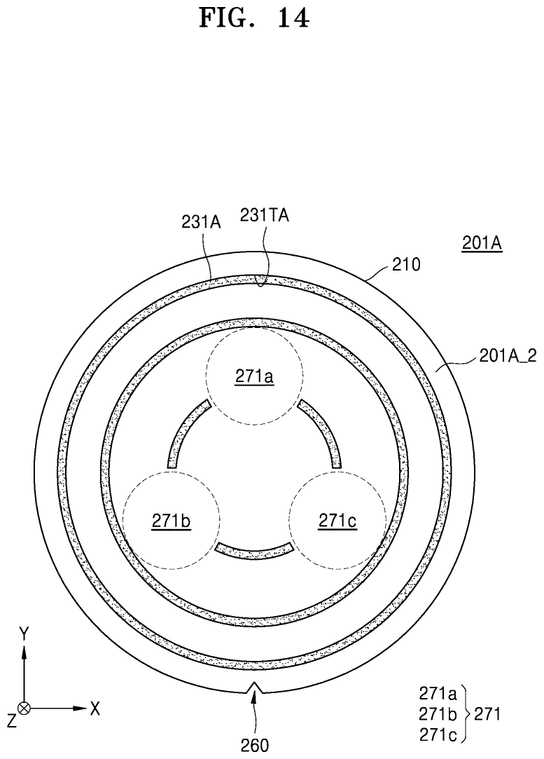

FIGS. 12A to 12C are top-down views of carrier substrates 200A, 200B, and 200C according to embodiments. FIGS. 13 and 14 are top-down views of carrier substrates 201 and 201A according to embodiments. Hereinafter, the differences from the carrier substrate 200 described with reference to FIGS. 10 and 11 are mainly described.

Referring to FIG. 12A, the carrier substrate 200A may include the main layer 210 and a rear trench 230TA (e.g., rear trenches) on a rear surface 200A_2 of the carrier substrate 200A. A rear organic pattern 230A may be inside the rear trench 230TA.

In some embodiments, the rear trench 230TA of the carrier substrate 200A may include a concentric shape. For example, the rear trench 230TA of the carrier substrate 200A may include one or more concentric shapes (e.g., concentric trenches). In one embodiment, the concentric trenches may have a constant interval therebetween. Each trench 230TA may have a circular shape, generally described as a curved line shape. Likewise, the rear organic pattern 230A of the carrier substrate 200A may include a concentric shape. For example, the rear organic pattern 230A of the carrier substrate 200A may include one or more concentric shapes (e.g., concentric line patterns). The concentric line patterns may each be a curved organic line pattern. The concentric line patterns may have a constant interval therebetween.

In some embodiments, the rear trench 230TA and the rear organic pattern 230A of the carrier substrate 200A may not be in the attachment region 270 on the rear surface 200A_2 of the carrier substrate 200A.

Referring to FIG. 12B, the carrier substrate 200B may include the main layer 210 and a rear trench 230TB on a rear surface 200B_2 of the carrier substrate 200B. A rear organic pattern 230B may be inside the rear trench 230TB.

In some embodiments, the rear trench 230TB of the carrier substrate 200B may include a concentric shape. For example, the rear trench 230TB of the carrier substrate 200B may include one or more concentric shapes (e.g., concentric trenches). In one embodiment, the concentric trenches have different intervals therebetween. Each trench 230TB may have a circular shape, also described as a curved line shape. Likewise, the rear organic pattern 230B of the carrier substrate 200B may include a concentric shape. For example, the rear organic pattern 230B of the carrier substrate 200B may include one or more concentric shapes (e.g., concentric line patterns). The concentric line patterns may each be a curved organic line pattern. The concentric line patterns may have different intervals therebetween.

In some embodiments, the rear trench 230TB and the rear organic pattern 230B of the carrier substrate 200B may not be in the attachment region 270 on the rear surface 200B_2 of the carrier substrate 200B.

Referring to FIG. 12C, the carrier substrate 200C may include the main layer 210 and a rear trench 230TC on a rear surface 200C_2 2 of the carrier substrate 200C. A rear organic pattern 230C may be inside the rear trench 230TC.

In some embodiments, the rear trench 230TC of the carrier substrate 200C may include a lattice shape and a concentric shape. For example, the rear trench 230TC of the carrier substrate 200C may include a lattice shape having lines extending in the first horizontal direction (the X direction) and the second horizontal direction (the Y direction) and one or more concentric shapes, for example, with a constant interval therebetween. Likewise, the rear organic pattern 230C of the carrier substrate 200C may include a lattice shape and a concentric shape. For example, the rear organic pattern 230C of the carrier substrate 200C may include a lattice shape having lines extending in the first horizontal direction (the X direction) and the second horizontal direction (the Y direction) and one or more concentric shapes, for example, with a constant interval therebetween.

In some embodiments, the rear trench 230TC and the rear organic pattern 230C of the carrier substrate 200C may not be in the attachment region 270 on the rear surface 200C_2, and so a plurality of rear organic line patterns 230C may terminate at the attachment region 270.

Referring to FIG. 13, the carrier substrate 201 may include the main layer 210 and a rear trench 231T on a rear surface 201_2 of the carrier substrate 201. A rear organic pattern 231 may be inside the rear trench 231T.

In some embodiments, the rear trench 231T and the rear organic pattern 231 of the carrier substrate 201 may include a lattice shape. For example, the rear trench 231T and the rear organic pattern 231 of the carrier substrate 201 may include a lattice shape of line patterns extending in the first horizontal direction (the X direction) and the second horizontal direction (the Y direction).

In some embodiments, the carrier substrate 201 may include an attachment region 271 on the rear surface 201_2. For example, the attachment region of the carrier substrate 201 may include a plurality of attachment regions 271a, 271b, and 271c (also described as attachment sub-regions). In some embodiments, the rear trench 231T and the rear organic pattern 231 of the carrier substrate 201 may not be formed in the attachment region 271. For example, two or more of the rear organic line patterns of the rear organic pattern 231 may terminate at each of the attachment regions 271a, 271b, and 271c.

Referring to FIG. 14, the carrier substrate 201A may include the main layer 210 and a rear trench 231TA on a rear surface 201A_2 of the carrier substrate 201A. A rear organic pattern 231A may be inside the rear trench 231TA.

In some embodiments, the rear trench 231TA and the rear organic pattern 231A of the carrier substrate 201A may include a concentric shape, for example, to have a plurality of rear organic curved line patterns (e.g., which may be in the shape of circles or arcs). In some embodiments, the rear trench 231TA and the rear organic pattern 231A of the carrier substrate 201A may not be formed in the attachment regions 271a, 271b, and 271c of the attachment region 271. For example, at least one of the concentric rear organic curved line patterns may be interrupted by one or more of the attachment regions 271a, 271b, and 271c. For example, the rear organic pattern 231A may include a plurality of arcs that each terminate at at least one of the attachment regions 271a, 271b, and 271c.

As described with reference to FIGS. 10 and 11, because the carrier substrates 200A, 200B, 200C, 201, and 201A shown in FIGS. 12A to 12C, 13, and 14 include the rear organic patterns 230A, 230B, 230C, 231, and 231A on the rear surfaces 200A_2, 200B_2, 200C_2, 201_2, and 201A_2 of the carrier substrates 200A, 200B, 200C, 201, and 201A, respectively, warpage of the carrier substrates 200A, 200B, 200C, 201, and 201A due to expansion and contraction may be reduced.

According to embodiments, the carrier substrates 200, 200A, 200B, 200C, 201, and 201A respectively including the rear organic patterns 230, 230A, 230B, 230C, 231, and 231A may be provided. Particularly, according to embodiments, the carrier substrates 200, 200A, 200B, 200C, 201, and 201A of which warpage due to expansion and contraction is reduced may be provided. According to the above embodiments, the main layer of the carrier substrates may be formed of a material such as silicon, germanium, glass, or alumina, and the rear organic patterns may be formed of an organic material, such as polymers, including thermoplastic polymers such as polyethylene (PE), polypropylene (PP), polycarbonate (PC), polystyrene (PS), and polyvinyl chloride (PVC), with a larger thermal expansion coefficient than that of the carrier substrate. However, these are exemplary and the organic materials of the present invention are not limited to the substances described above.

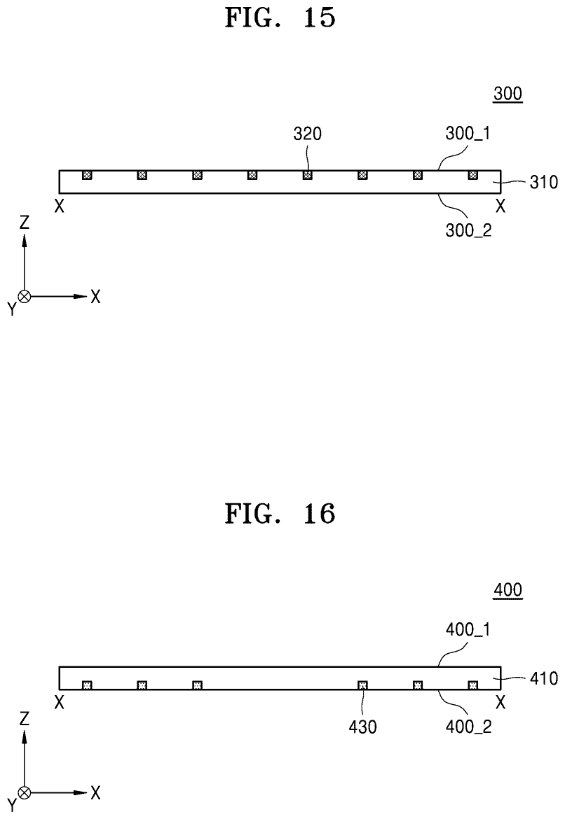

FIGS. 15 to 18 are cross-sectional views of carrier substrates 300, 400, 500, and 501 according to embodiments. Hereinafter, the differences from the carrier substrate 100 described with reference to FIGS. 1 to 3 are mainly described.

Referring to FIG. 15, the carrier substrate 300 may include a front surface 300_1 and a rear surface 300_2 opposite to each other and a main layer 310. The carrier substrate 300 may include a front trench (not labeled) on the front surface 300_1 and a front organic pattern 320 inside the front trench. In some embodiments, the thermal expansion coefficient of the main layer 310 of the carrier substrate 300 may be greater than the thermal expansion coefficient of the front organic pattern 320.

Referring to FIG. 16, the carrier substrate 400 may include a front surface 400_1 and a rear surface 400_2 opposite to each other and a main layer 410. The carrier substrate 400 may include a rear trench (not labeled) on the rear surface 400_2 and a rear organic pattern 430 inside the rear trench. In some embodiments, the thermal expansion coefficient of the main layer 410 of the carrier substrate 400 may be greater than the thermal expansion coefficient of the rear organic pattern 430. For example, in the embodiments of FIGS. 16 and 17, the main layer of the carrier substrate 300 or carrier substrate 400 may be formed of a material such as silicon, germanium, glass, or alumina, and the front organic pattern 320 or rear organic pattern 430 may be formed of an organic material, such as polymers, including thermosetting polymers such as epoxy resin, phenolic resin, unsaturated polyester resin, silicone resin, and melamine-formaldehyde resin, with a smaller thermal expansion coefficient than that of the respective carrier substrate. However, these are exemplary and the organic materials of the present invention are not limited to the substances described above.

Referring to FIG. 17, the carrier substrate 500 may include a front surface 500_1 and a rear surface 500_2 opposite to each other and a main layer 510. The carrier substrate 500 may include a front trench (not labeled) on the front surface 500_1 and a front organic pattern 520 inside the front trench. The carrier substrate 500 may include a rear trench (not labeled) in the rear surface 500_2 and a rear organic pattern 530 inside the rear trench.

In some embodiments, some of front organic patterns 520 on the front surface 500_1 of the carrier substrate 500 and rear organic patterns 530 on the rear surface 500_2 may overlap each other in the vertical direction (the Z direction).

In some embodiments, the thermal expansion coefficient of the front organic pattern 520 on the front surface 500_1 of the carrier substrate 500 may be greater than the thermal expansion coefficient of the main layer 510. In some embodiments, the thermal expansion coefficient of the rear organic pattern 530 on the rear surface 500_2 of the carrier substrate 500 may be greater than the thermal expansion coefficient of the main layer 510. In some embodiments, both the thermal expansion coefficient of the front organic pattern 520 on the front surface 500_1 of the carrier substrate 500 is greater than the thermal expansion coefficient of the main layer 510, and the thermal expansion coefficient of the rear organic pattern 530 on the rear surface 500_2 of the carrier substrate 500 is greater than the thermal expansion coefficient of the main layer 510. In this embodiment, the main layer 510 of the carrier substrate 500 may be formed of a material such as silicon, germanium, glass, or alumina, and the front organic pattern 520 may be formed of an organic material, such as polymers, including thermoplastic polymers such as polyethylene (PE), polypropylene (PP), polycarbonate (PC), polystyrene (PS), and polyvinyl chloride (PVC), with a greater thermal expansion coefficient than that of the carrier substrate 500, and the rear organic pattern 530 may be formed of an organic material, such as polymers, including thermoplastic polymers such as polyethylene (PE), polypropylene (PP), polycarbonate (PC), polystyrene (PS), and polyvinyl chloride (PVC), with a greater thermal expansion coefficient than that of the carrier substrate 500. However, these are exemplary and the organic materials of the present invention are not limited to the substances described above.

In some embodiments, the front organic pattern 520 and the rear organic pattern 530 may include materials having the same thermal expansion coefficient, respectively. For example, the front organic pattern 520 and the rear organic pattern 530 may include the same material.

In some embodiments, the front organic pattern 520 and the rear organic pattern 530 may include materials having different thermal expansion coefficients, respectively. For example, the thermal expansion coefficient of the front organic pattern 520 may be greater than the thermal expansion coefficient of the rear organic pattern 530. For example, the thermal expansion coefficient of the front organic pattern 520 may be less than the thermal expansion coefficient of the rear organic pattern 530.

Referring to FIG. 18, the carrier substrate 501 may include a front surface 501_1 and a rear surface 501_2 opposite to each other and the main layer 510. The carrier substrate 501 may include a front trench (not labeled) on the front surface 501_1 and a front organic pattern 521 inside the front trench. The carrier substrate 501 may include a rear trench (not labeled) on the rear surface 501_2 and a rear organic pattern 531 inside the rear trench.

In some embodiments, the front organic pattern 521 (e.g., certain front organic line patterns) on the front surface 501_1 of the carrier substrate 501 and the rear organic pattern 531 on the rear surface 501_2 (e.g., certain rear organic line patterns) may not overlap each other in the vertical direction (the Z direction).

In some embodiments, the thermal expansion coefficient of the front organic pattern 521 on the front surface 501_1 of the carrier substrate 501 may be greater than the thermal expansion coefficient of the main layer 510. In some embodiments, the thermal expansion coefficient of the rear organic pattern 531 on the rear surface 501_2 of the carrier substrate 501 may be greater than the thermal expansion coefficient of the main layer 510.

In some embodiments, the front organic pattern 521 and the rear organic pattern 531 may include materials having the same thermal expansion coefficient, respectively. For example, the front organic pattern 521 and the rear organic pattern 531 may include the same material.

In some embodiments, the front organic pattern 521 and the rear organic pattern 531 may include materials having different thermal expansion coefficients, respectively. For example, the thermal expansion coefficient of the front organic pattern 521 may be greater than the thermal expansion coefficient of the rear organic pattern 531. For example, the thermal expansion coefficient of the front organic pattern 521 may be less than the thermal expansion coefficient of the rear organic pattern 531.

The materials used for the carrier substrate 501, the front organic pattern 521, and the rear organic patter 531 may be the same as those discussed above in connection with FIG. 17.

FIGS. 19A to 19M are cross-sectional views illustrating a method of manufacturing the semiconductor package 10, according to embodiments. Particularly, FIGS. 19A to 19M are cross-sectional views for describing a method of manufacturing the carrier substrate 100 described with reference to FIGS. 1 to 3 and a method of manufacturing the semiconductor package 10 by using the carrier substrate 100. FIGS. 19A to 19C are cross-sectional views for describing a method of manufacturing the carrier substrate 100. FIGS. 19D to 19M are cross-sectional views for describing a method of manufacturing the semiconductor package 10 by using the carrier substrate 100. Particularly, FIGS. 19D to 19I are magnified cross-sectional views of a partial region of FIG. 19C.

Referring to FIG. 19A, the main layer 110 may be provided. A photoresist pattern PR may be provided on the main layer 110. The photoresist pattern PR may expose a partial region of the main layer 110 therethrough. For example, the photoresist pattern PR may expose a partial region of the main layer 110 on which the front trench 120T is formed in a process to be described below.

Referring to FIG. 19B, the partial region of the main layer 110 may be etched using the photoresist pattern PR as an etching mask. As a result, the front trench 120T may be formed on the front surface of the main layer 110. A process of forming the front trench 120T may be performed using a dry etching process and/or a wet etching process.

Referring to FIG. 19C, the front organic pattern 120 may be formed inside the front trench 120T. A process of forming the front organic pattern 120 may include coating the front trench 120T and the front surface of the main layer 110 with an organic material and then removing a portion of the organic material on the front surface of the main layer 110. As a result, the carrier substrate 100 including the main layer 110 and the front organic pattern 120 on the front surface 100_1 may be produced.

Referring to FIG. 19D, a plurality of pads 151 may be formed on the front surface 100_1 of the carrier substrate 100. The plurality of pads 151 may be formed at locations, which do not overlap the front organic pattern 120 in the vertical direction (the Z direction). The plurality of pads 151 may be terminal connection pads to which a plurality of external connection terminals 191 (see FIG. 19M) are attached in a process to be described below.

Thereafter, a first redistribution insulating layer 153_1 covering the plurality of pads 151 may be formed on the front surface 100_1 of the carrier substrate 100. Thereafter, a portion of the first redistribution insulating layer 153_1 may be etched to expose the plurality of pads 151. In some embodiments, the thermal expansion coefficient of the first redistribution insulating layer 153_1 may be greater than the thermal expansion coefficient of the main layer 110.

In some embodiments, the first redistribution insulating layer 153_1 may include an organic material. The first redistribution insulating layer 153_1 may be formed of, for example, a material layer including an organic compound. In some embodiments, the first redistribution insulating layer 153_1 may be formed of a material layer including an organic polymer material. In some embodiments, the first redistribution insulating layer 153_1 may be formed of photosensitive polyimide (PSPI).

In some embodiments, the thermal expansion coefficient of the organic material included in the first redistribution insulating layer 153_1 may be substantially the same as the thermal expansion coefficient of the organic material of the front organic pattern 120 of the carrier substrate 100.

In some embodiments, the thermal expansion coefficient of the organic material included in the first redistribution insulating layer 153_1 may be greater or less than the thermal expansion coefficient of the organic material of the front organic pattern 120 of the carrier substrate 100. The material of the front organic pattern 120 of the carrier substrate 100 may be variously changed according to designs.

Referring to FIG. 19E, a first redistribution pattern 152_1 electrically connected to the plurality of pads 151 exposed through the first redistribution insulating layer 153_1 may be formed. In some embodiments, the first redistribution pattern 152_1 may include a conductive material. For example, the first redistribution pattern 152_1 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof but is not limited thereto.

Referring to 19F, a second redistribution insulating layer 153_2 covering the first redistribution pattern 152_1 may be formed on the first redistribution insulating layer 153_1. Thereafter, a portion of the second redistribution insulating layer 153_2 may be etched to expose a partial region of the first redistribution pattern 152_1.

Referring to FIG. 19G, a second redistribution pattern 152_2 electrically connected to the first redistribution pattern 152_1 exposed through the second redistribution insulating layer 153_2 may be formed.

Thereafter, a third redistribution insulating layer 153_3 covering the second redistribution pattern 152_2 may be formed on the second redistribution insulating layer 153_2. Thereafter, a portion of the third redistribution insulating layer 153_3 may be etched to expose a partial region of the second redistribution pattern 152_2.

As a result, a redistribution layer 150 including a plurality of redistribution insulating layers 153 and a plurality of redistribution patterns 152 may be formed on the front surface 100_1 of the carrier substrate 100.

Referring to FIG. 19H, a solder 185 may be formed on the second redistribution pattern 152_2 exposed through the third redistribution insulating layer 153_3. In some embodiments, the solder 185 may include a conductive material. For example, the solder 185 may include Sn, lead (Pb), silver (Ag), Cu, or a combination thereof. A plurality of solders may be formed.

Referring to FIGS. 19I and 19J, the semiconductor chip 180 may be mounted on the solder 185. A chip connection pad 181 may be on an active surface of the semiconductor chip 180. The semiconductor chip 180 may be electrically connected to the plurality of redistribution patterns 152 of the redistribution layer 150 via the chip connection pad 181 and the solder 185.

In some embodiments, the semiconductor chip 180 may not overlap the front organic pattern 120 on the front surface 100_1 of the carrier substrate 100 in the vertical direction (the Z direction). A reflow process may be performed to form a plurality of solder bumps or balls connecting and bonding the semiconductor chip to the redistribution substrate formed by the process of FIGS. 19A through 19H. During the reflow process, the device under manufacture may be heated and then cooled. During the process, the front organic pattern 120 may reduce or prevent warping of the device under manufacture.

In some embodiments, the semiconductor chip 180 may be, for example, a central processing unit (CPU) chip, a graphics processing unit (GPU) chip, or an application processor (AP) chip. In some embodiments, the semiconductor chip 180 may be, for example, a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

Referring to FIG. 19K, the molding layer 190 molding the redistribution layer 150, the solder 185, and the semiconductor chip 180 may be formed. The molding layer 190 may surround the redistribution layer 150, a plurality of solders 185, and a plurality of semiconductor chips 180. In some embodiments, the thermal expansion coefficient of the molding layer 190 may be greater than the thermal expansion coefficient of the main layer 110. The molding layer 190 may include epoxy resin, silicon resin, or a combination thereof. For example, the molding layer 190 may include an epoxy mold compound (EMC).

Referring to FIG. 19L, the carrier substrate 100 may be removed. Particularly, the carrier substrate 100 may be debonded (e.g., detached) from the bonded redistribution layer 150 and the semiconductor chip 180.

Referring to FIG. 19M, the redistribution layer 150 and the molding layer 190 may be cut. By doing this, the molding layer 190 may surround one semiconductor chip 180. Thereafter, the plurality of external connection terminals 191 electrically connected to the plurality of pads 151, respectively, may be formed. In some embodiments, an external connection terminal 191 may include a conductive material. For example, the external connection terminal 191 may include Sn, Pb, Ag, Cu, or a combination thereof. Via the plurality of external connection terminals 191, the semiconductor package 10 may be electrically connected to an external device.

According to embodiments, a method of manufacturing the semiconductor package 10 by using the carrier substrate 100 including the front organic pattern 120 may be used. Particularly, because the carrier substrate 100 includes the front organic pattern 120 on the front surface 100_1 of the carrier substrate 100, warpage of the carrier substrate 100, which may occur during a process of manufacturing the semiconductor package 10, may be reduced.

For example, the process of manufacturing the semiconductor package 10 may include a process of forming the plurality of redistribution insulating layers 153 having a thermal expansion coefficient that is greater than the thermal expansion coefficient of the main layer 110 on the front surface 100_1 of the carrier substrate 100. In addition, the process of manufacturing the semiconductor package 10 may include heating and cooling processes.

Therefore, because the carrier substrate 100 including the front organic pattern 120 according to embodiments is provided, warpage of the carrier substrate 100, which may occur due to the thermal expansion coefficient difference from the plurality of redistribution insulating layers 153 while performing the process of manufacturing the semiconductor package 10, may be reduced. The same result may be obtained by using the rear organic patterns discussed in connection with various embodiments.

In addition, by reducing the warpage of the carrier substrate 100, which may occur during the process of manufacturing the semiconductor package 10, the performance and the reliability of the semiconductor package 10 may be improved. That is, according to embodiments, a method of manufacturing the semiconductor package 10 with improved performance and reliability may be provided.

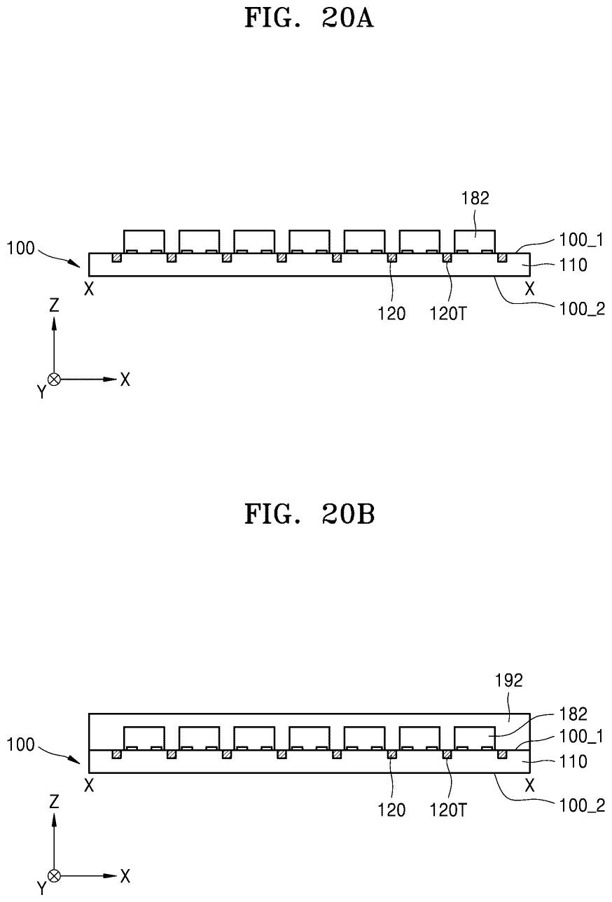

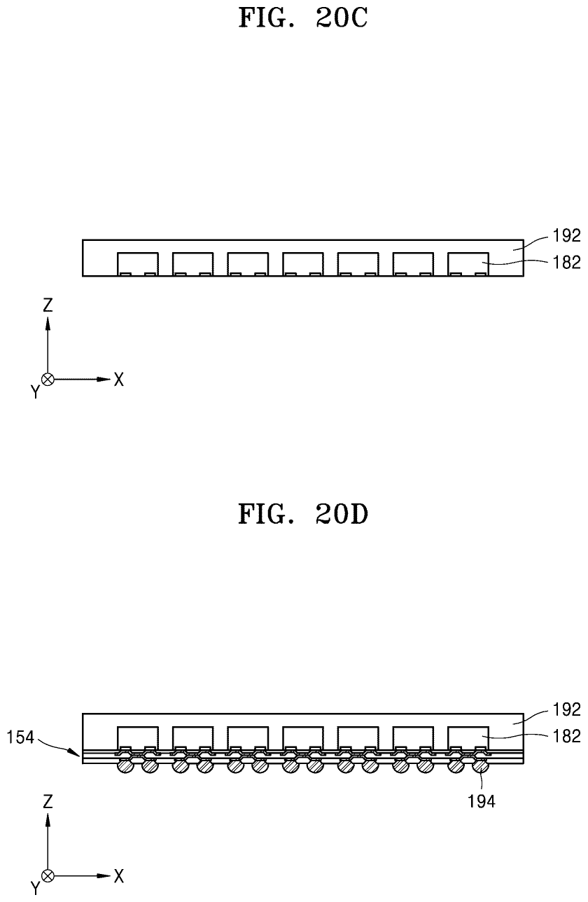

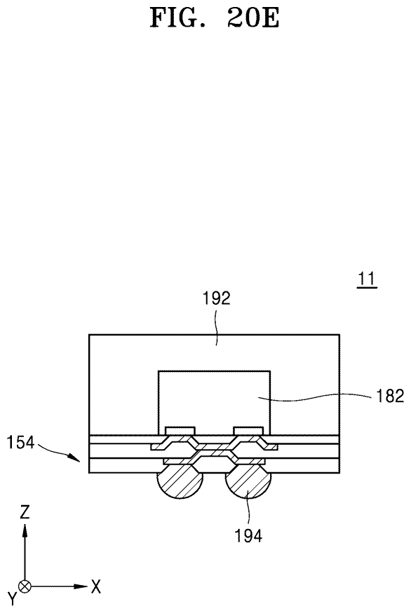

FIGS. 20A to 20E are cross-sectional views illustrating a method of manufacturing a semiconductor package 11, according to embodiments. Particularly, FIGS. 20A to 20E are cross-sectional views for describing a method of manufacturing the semiconductor package 11, which is performed next to FIG. 19C. FIGS. 20A to 20E are cross-sectional views for describing a method of manufacturing the semiconductor package 11 by using the carrier substrate 100.

Referring to FIG. 20A, a semiconductor chip 182 may be mounted on the front surface 100_1 of the carrier substrate 100. The semiconductor chip 182 may include a chip connection pad (not labeled) on an active surface thereof.

In some embodiments, the semiconductor chip 182 may not overlap the front organic pattern 120 on the front surface 100_1 of the carrier substrate 100 in the vertical direction (the Z direction). For example, the semiconductor chip 182 may be between every two front organic patterns 120.

In some embodiments, the semiconductor chip 182 may be disposed such that the chip connection pad faces the front surface 100_1 of the carrier substrate 100. In some embodiments, unlike shown in FIG. 20A, the semiconductor chip 182 may be disposed such that the chip connection pad is opposite to the front surface 100_1 of the carrier substrate 100.

Referring to FIG. 20B, a molding layer 192 molding the semiconductor chip 182 may be formed. The molding layer 192 may surround a plurality of semiconductor chips 182 on the front surface 100_1 of the carrier substrate 100. The thermal expansion coefficient of the molding layer 192 may be greater than the thermal expansion coefficient of the main layer 110 of the carrier substrate 100.

Referring to FIG. 20C, the carrier substrate 100 may be removed. Particularly, the carrier substrate 100 may be debonded from the semiconductor chip 182.

Referring to FIG. 20D, a redistribution layer 154 may be formed on the active surface of the semiconductor chip 182. The redistribution layer 154 may include at least one redistribution insulating layer and a redistribution pattern. The redistribution pattern may penetrate at least a portion of the at least one redistribution insulating layer. The semiconductor chip 182 may be electrically connected to the redistribution pattern of the redistribution layer 154. Thereafter, an external connection terminal 194 may be formed on an exposed portion of the redistribution pattern.

Referring to FIG. 20E, the semiconductor package 11 may be formed by cutting the redistribution layer 154 and the molding layer 192. By doing this, the molding layer 192 may surround one semiconductor chip 182.

According to embodiments, a method of manufacturing the semiconductor package 11 by using the carrier substrate 100 including the front organic pattern 120 may be provided. Particularly, because the carrier substrate 100 includes the front organic pattern 120 on the front surface 100_1 of the carrier substrate 100, warpage of the carrier substrate 100, which may occur during a process of manufacturing the semiconductor package 11, may be reduced.

For example, the process of manufacturing the semiconductor package 11 may include a process of forming the molding layer 192 having a thermal expansion coefficient that is greater than the thermal expansion coefficient of the main layer 110 on the front surface 100_1 of the carrier substrate 100. In addition, the process of manufacturing the semiconductor package 11 may include heating and cooling processes. For example, the heating and cooling processes may occur during the process of forming the molding layer (192).

Therefore, because the carrier substrate 100 including the front organic pattern 120 according to embodiments is provided, warpage of the carrier substrate 100, which may occur due to the thermal expansion coefficient difference from the molding layer 192 while performing the process of manufacturing the semiconductor package 11, may be reduced.

In addition, by reducing the warpage of the carrier substrate 100, which may occur during the process of manufacturing the semiconductor package 11, the performance and the reliability of the semiconductor package 11 may be improved. That is, according to embodiments, a method of manufacturing the semiconductor package 11 with improved performance and reliability may be provided.

The same carrier substrate 100, or carrier substrates formed of the same base material (e.g., same main layer) may be used for both the method of FIGS. 19A-19M and the method of FIGS. 20A-20E. Therefore, for different methods of forming semiconductor packages, different carrier substrates with different thermal expansion coefficients do not need to be used, and a single carrier substrate or base material carrier substrate such as described in connection with the various embodiments can be used.

While the inventive concept has been particularly shown and described with reference to embodiments thereof, it will be understood that various changes in form and details may be made therein without departing from the spirit and scope of the following claims.

What is claimed is:

1. A carrier substrate comprising:
a first surface and a second surface opposite to each other;
a main layer comprising and extending between the first surface and the second surface;
a first trench extending from the first surface of the carrier substrate into the main layer; and
a first organic pattern inside the first trench.

2. The carrier substrate of claim 1, wherein a thermal expansion coefficient of the main layer is less than a thermal expansion coefficient of the first organic pattern.

3. The carrier substrate of claim 1, wherein a thermal expansion coefficient of the main layer is greater than a thermal expansion coefficient of the first organic pattern.

4. The carrier substrate of claim 1, further comprising:
a second trench extending from the second surface of the carrier substrate into the main layer; and
a second organic pattern inside the second trench.

5. The carrier substrate of claim 4, wherein the first organic pattern and the second organic pattern include different materials, respectively.

6. The carrier substrate of claim 4, wherein a thermal expansion coefficient of the main layer is less than a thermal expansion coefficient of the second organic pattern.

7. The carrier substrate of claim 1, wherein the first trench has a lattice shape from a top-down view.

8. The carrier substrate of claim 1, wherein the first trench has a concentric shape from a top-down view.

9. A method of manufacturing a semiconductor package, the method comprising:
providing a carrier substrate;
disposing a semiconductor chip on the carrier substrate; and
forming a redistribution layer electrically connected to the semiconductor chip,
wherein the carrier substrate comprises:
a first surface and a second surface opposite to each other;
a main layer comprising and extending between the first surface and the second surface;
a first trench extending from the first surface of the carrier substrate into the main layer; and
a first organic pattern inside the first trench.

10. The method of claim 9, wherein a thermal expansion coefficient of the main layer is less than a thermal expansion coefficient of the first organic pattern.

11. The method of claim 9, wherein the disposing of the semiconductor chip on the carrier substrate is performed after forming the redistribution layer.

12. The method of claim 11, wherein the forming of the redistribution layer comprises:
forming a redistribution insulating layer on the first surface of the carrier substrate; and
forming a redistribution pattern surrounded by the redistribution insulating layer,
wherein the semiconductor chip is disposed on the redistribution layer and electrically connected to the redistribution pattern, and
wherein the thermal expansion coefficient of the main layer is less than a thermal expansion coefficient of the redistribution insulating layer.

13. The method of claim 9, wherein the forming of the redistribution layer is performed after the disposing of the semiconductor chip on the carrier substrate.

14. The method of claim 13, wherein the semiconductor chip is disposed on the first surface of the carrier substrate,
further comprising forming a molding layer molding the semiconductor chip after the disposing of the semiconductor chip and before the forming of the redistribution layer, and
wherein a thermal expansion coefficient of the main layer is less than a thermal expansion coefficient of the molding layer.

15. The method of claim 9, wherein no organic patterns formed in the carrier substrate overlap the semiconductor chip from a top-down view when the semiconductor chip is mounted on the carrier substrate.

16. The method of claim 9, wherein the semiconductor chip is disposed on the second surface of the carrier substrate, and the redistribution layer is formed on the second surface of the carrier substrate.

17. The method of claim 9, wherein the carrier substrate further comprises:
a second trench on the second surface; and
a second organic pattern inside the second trench.

18. A method of manufacturing a semiconductor package, the method comprising:
providing a carrier substrate;
forming, on a front surface of the carrier substrate, a redistribution layer including a redistribution insulating layer and a redistribution pattern surrounded by the redistribution insulating layer; and
disposing a semiconductor chip on the redistribution layer and electrically connecting the semiconductor chip to the redistribution pattern,
wherein the carrier substrate comprises:
the front surface and a rear surface opposite to the front surface;
a main layer comprising and extending between the rear surface and the front surface;
a front trench extending from the front surface of the carrier substrate into the main layer; and
a front organic pattern inside the front trench,
wherein a thermal expansion coefficient of the main layer is less than a thermal expansion coefficient of the front organic pattern, and the thermal expansion coefficient of the main layer is less than a thermal expansion coefficient of the redistribution insulating layer.

19. The method of claim 18, wherein the front trench has a lattice shape in a top-down view.

20. The method of claim 18, further comprising:
forming, on the front surface of the carrier substrate, a molding layer molding the redistribution layer and the semiconductor chip; and
after forming the molding layer, debonding the carrier substrate from the redistribution layer, the semiconductor chip, and the molding layer.
